(19) United States
(12) Patent Application Publication
(10) Pub. No.: US 2012/0092035 A1
(43) Pub. Date: Apr. 19, 2012

(54) ADAPTED TEST APPARATUS FOR ELECTRONIC COMPONENTS

(76) Inventor: Wen-Hsien Lo, Miaoli County (TW)

(21) Appl. No.: 13/271,721

(22) Filed: Oct. 12, 2011

(30) Foreign Application Priority Data
Oct. 15, 2010 (TW) 099135226

(51) Int. Cl. G01R 31/00

(52) U.S. Cl. 324/756.07

(57) ABSTRACT

An adapted test apparatus for electronic components includes a case assembly, a plurality of first motherboard assemblies and a handler. The first motherboard assemblies are disposed in the case assembly. Each first motherboard assembly includes a motherboard, a first main connector, an adapter, a plurality of test connectors and a central processing unit (CPU). The motherboard is vertically disposed in the case assembly. The first main connector is disposed on the motherboard and electrically connected to the motherboard. The adapter is electrically connected to the first main connector and substantially perpendicular to the motherboard. The test connector is disposed on the adapter. The CPU is disposed on the motherboard and electrically connected to the motherboard. The handler inserts a plurality of electronic components into the test connectors in a vertical direction, tests the electronic components and removes the electronic components after the electronic components are tested.

This application claims priority of No. 099135226 filed in Taiwan R.O.C. on Oct. 15, 2010 under 35 USC 119, the entire content of which is hereby incorporated by reference.

### BACKGROUND OF THE INVENTION

1. Field of the Invention

The invention relates in general to a test apparatus, and more particularly to an adapted test apparatus for electronic components.

2. Related Art

A conventional method for testing an integrated circuit is usually performed in an artificial manner using a dedicated test apparatus. For example, the integrated circuit may be inserted into a test circuit board, which is then powered on to perform the test, and the tester can watch the test result and classify the tested integrated circuit according to the test result.

Although the integrated circuit can be inserted and removed through a robot arm, the test circuit board must be placed horizontally so that the robot arm can insert the integrated circuit into the socket on the test circuit board. However, the test circuit board needs to have a central processing unit (CPU), a heat dissipating module, a display module and the like, and thus occupies a relatively large horizontal area. If a lot of integrated circuits have to be tested, a lot of test circuit boards are needed and only can be placed horizontally. In this manner, a relatively large space is occupied, it is disadvantageous to the minimization of the test place, and the test cost is thus increased.

### SUMMARY OF THE INVENTION

It is therefore an object of the invention to provide an adapted test apparatus for automatically testing integrated circuits to save the test space and decrease the test cost.

To achieve the above-identified object, the invention provides an adapted test apparatus including a case assembly, a plurality of first motherboard assemblies and a handler. Each first motherboard assembly is disposed in the case assembly and includes a motherboard vertically disposed in the case assembly; a first main connector, which is disposed on the motherboard and electrically connected to the motherboard; an adapter, which is electrically connected to the first main connector and substantially perpendicular to the motherboard; a plurality of test connectors disposed on the adapter; and a central processing unit (CPU), which is disposed on the motherboard and electrically connected to the motherboard. The handler inserts a plurality of electronic components into the test connectors in a vertical direction, respectively, tests the electronic components and removes the electronic components after the electronic components have been tested.

According to the above-mentioned adapted test apparatus, the larger test capacity can be obtained in the limited space, and the test cost can be effectively reduced.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is an overall schematic illustration showing an adapted test apparatus according to a first embodiment of the invention.

FIG. 2 is a partial schematic illustration showing the adapted test apparatus of FIG. 1.

FIG. 3 is a partial pictorial view showing the adapted test apparatus of FIG. 1.

FIG. 4 is a cross-sectional view showing a positioning-pressing mechanism according to a second embodiment of the invention.

FIG. 5 is a partial schematic illustration showing an adapted test apparatus according to the second embodiment of the invention.

FIGS. 6 and 7 are partial schematic illustrations showing the adapted test apparatus according to the second embodiment of the invention.

FIG. 8 shows the connection relationships between a handler, a power supply and a motherboard according to the invention.

### DETAILED DESCRIPTION OF THE INVENTION

The present invention will be apparent from the following detailed description, which proceeds with reference to the accompanying drawings, wherein the same references relate to the same elements.

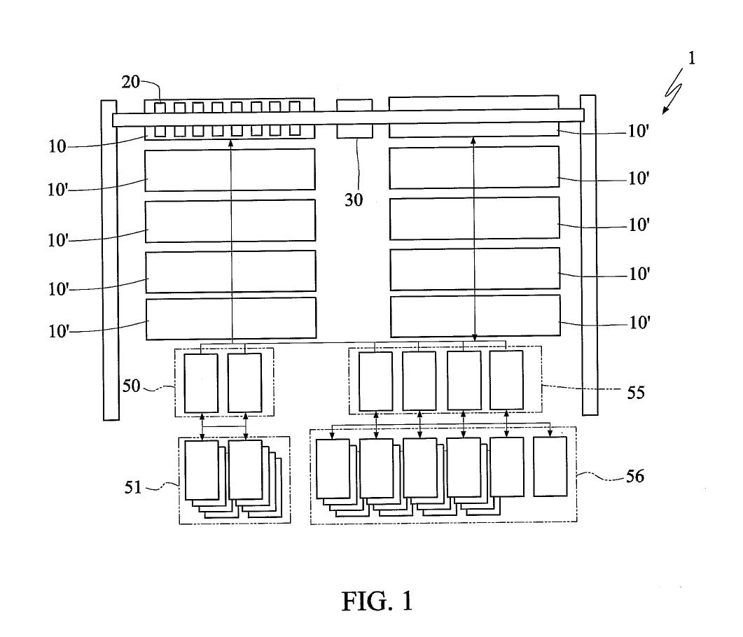

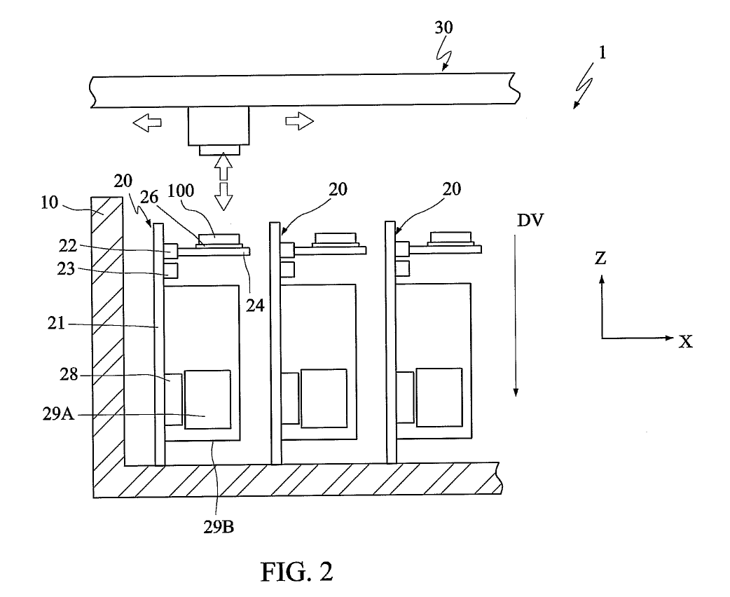

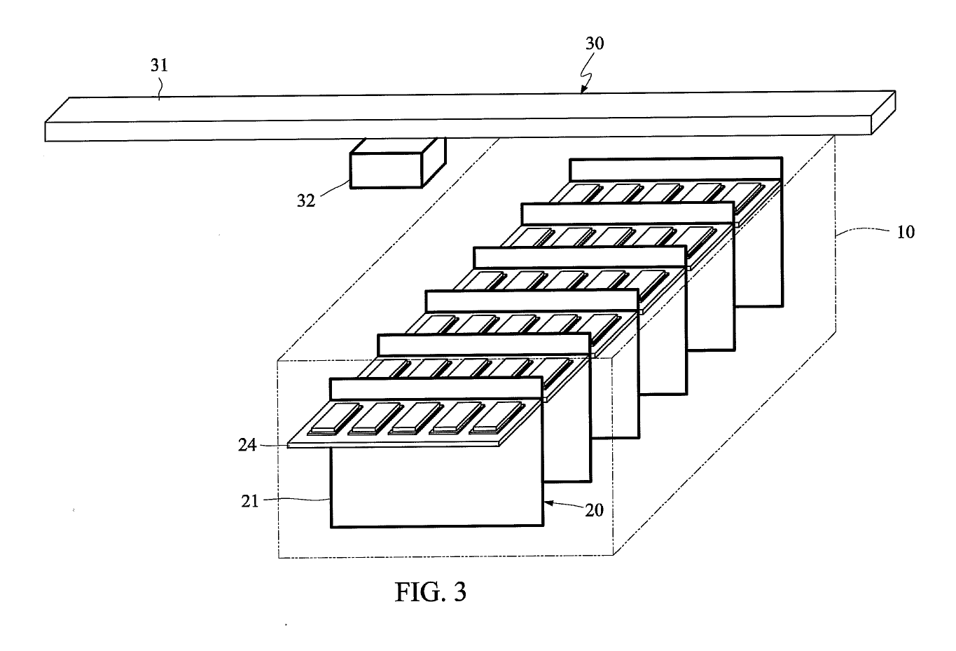

FIG. 1 is an overall schematic illustration showing an adapted test apparatus 1 according to a first embodiment of the invention. FIG. 2 is a partial schematic illustration showing the adapted test apparatus 1 of FIG. 1. FIG. 3 is a partial pictorial view showing the adapted test apparatus 1 of FIG. 1.

Referring to FIGS. 1 to 3, the adapted test apparatus 1 according to this embodiment includes a case assembly 10, a plurality of first motherboard assemblies 20 and a handler 30. Of course, the test apparatus 1 may further include a plurality of additional case assemblies 10′. The function of the additional case assembly 10′ is similar to the case assembly 10 so that the test capacity can be increased. The internal structure of one single case assembly 10 will be described in the following.

Each first motherboard assembly 20 is disposed in the case assembly 10 and includes a motherboard 21, a first main connector/socket 22, an adapter 24, a test connector/socket 26 and a central processing unit (CPU) 28. The motherboards 21 may be selected from various brands of commercial available motherboards and are vertically disposed in the case assembly 10. Consequently, specific motherboards may be purchased according to the customer's requirements, and the integrated circuits may be tested on the specific motherboards. Of course, a dedicated motherboard may also be used for the test. The first main connector 22 is disposed on the motherboard 21 and electrically connected to the motherboard 21. The adapter 24 is electrically connected to the first main connector 22 and substantially perpendicular to the motherboard 21. The adapter 24 may be a single adapter board or may include an adapter board, mounted on the case assembly 10 or the first motherboard assembly 20, and a cable electrically connecting the adapter board to the first main connector 22. The test connector 26 is disposed on the adapter 24. The CPU 28 is disposed on the motherboard 21 and electrically connected to the motherboard 21.

The handler 30 inserts a plurality of electronic components 100 into the test connectors 26 in a vertical direction DV, respectively, tests the electronic components 100 and removes the electronic components 100 after the electronic components 100 have been tested. The electronic component 100 may be an integrated circuit (IC) mounted on, for example, a memory module, such as a DIMM memory module. The handler 30 includes a suspension frame 31 and a robot arm 32 and may further include associated modules for performing data processing and controlling the classifying procedures. The robot arm 32 may move along the suspension frame 31 (in the X-axis direction), the suspension frame 31 may also be moved in the Y-axis direction, and the robot arm 32 of the handler 30 may take and move one or more than one electronic component 100 at a time in the Z-axis direction. The robot arm 32 may suck the integrated circuit using a sucker, for example.

In addition, the test apparatus 1 may further include a temporary storage area 50, a storage area 51, a coarse classification area 55 and a fine classification area 56. The handler 30 takes the electronic components 100 from the temporary storage area 50 and inserts the electronic components 100 into the test connectors 26, respectively. The handler 30 moves the tested electronic components 100 to the coarse classification area 55 according to a plurality of test results (e.g., normal or abnormal results), respectively. The electronic components 100, which have not been tested, can be placed in the storage area 51, and then placed in the fine classification area 56 after being tested.

It is to be noted that another handler (not shown) may be provided to move the electronic components 100 from the storage area 51 to the temporary storage area 50 or from the coarse classification area 55 to the fine classification area 56. Of course, the handler 30 may further perform the above-mentioned operations.

In addition, each first motherboard assembly 20 may further include a second main connector/socket 23, a heat dissipating fan 29A and a video card 29B. The second main connector 23 is disposed on the motherboard 21 and electrically connected to the motherboard 21. Of course, another adapter may be connected to the second main connector 23 so that more electronic components 100 can be tested. The heat dissipating fan 29A is disposed on the CPU 28. The video card 29B is electrically connected to and disposed on the motherboard 21. A display (not shown) may be connected to the video card 29B so that the tester can watch the test condition and result. However, the video card 29B is not an essential element because the data in all the test processes can be monitored and processed by the handler 30.

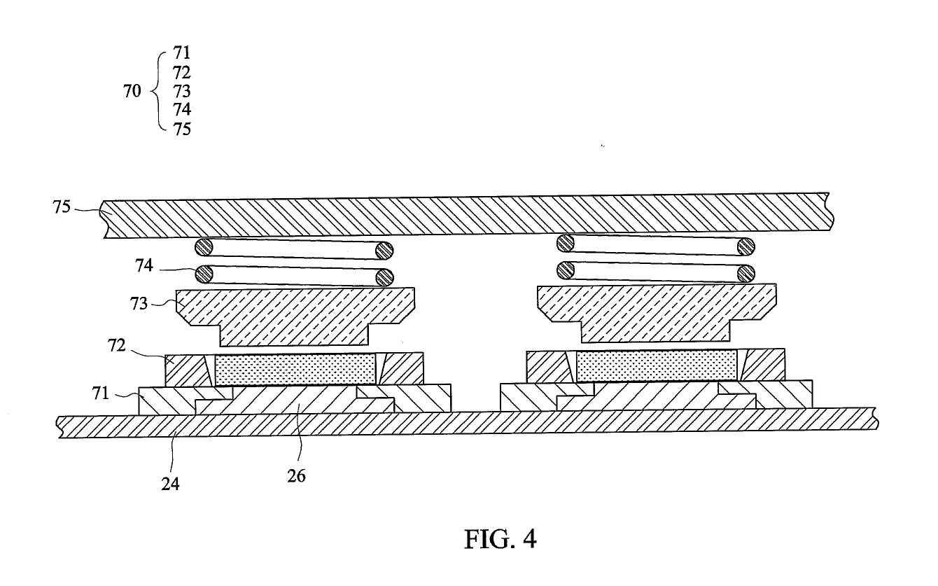

FIG. 4 is a cross-sectional view showing a positioning-pressing mechanism according to a second embodiment of the invention. As shown in FIG. 4, the test apparatus of this embodiment is similar to the first embodiment except that the test apparatus further includes a positioning-pressing mechanism 70, disposed on the adapter 24, for positioning the electronic component 100 and presses the electronic component 100 into the test connector 26. The positioning-pressing mechanism 70 may be separated from the handler 30, and may also be integrated with the handler 30. The positioning-pressing mechanism 70 includes a first positioning structure 71, a second positioning structure 72, a pressing block 73, a pressing mechanism 74 and a second suspension frame 75. The first positioning structure 71 is aligned with and disposed on the test connector 26. The second positioning structure 72, aligned with and disposed on the first positioning structure 71, positions the electronic component 100. The pressing block 73 presses the electronic component 100 into the test connector 26. The pressing mechanism 74, such as a spring, exerts a force on the pressing block 73 to press the pressing block 73. The pressing mechanism 74 is movably mounted on the second suspension frame 75.

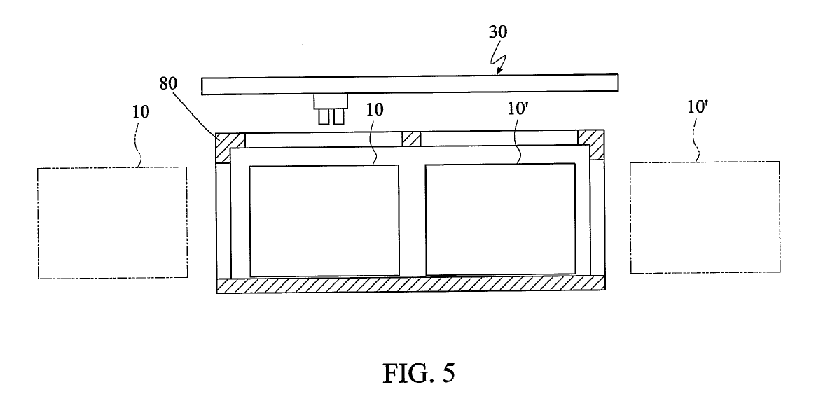

FIG. 5 is a partial schematic illustration showing an adapted test apparatus according to the second embodiment of the invention. As shown in FIG. 5, this embodiment is similar to the first embodiment except that the case assembly 10 and the additional case assemblies 10′ are disposed in a machine casing 80, and may be moved out of the machine casing 80 for maintenance.

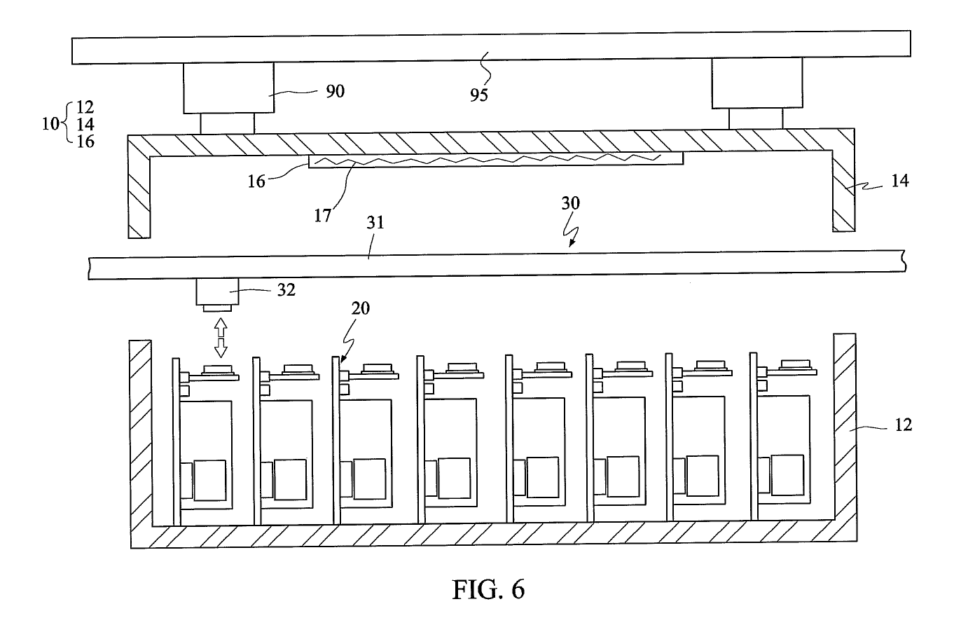

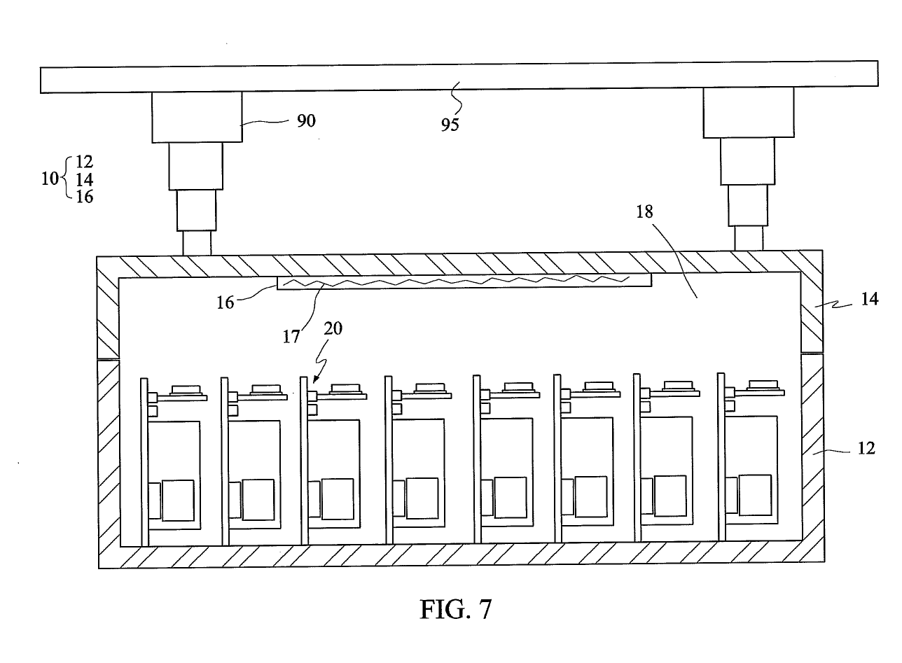

FIGS. 6 and 7 are partial schematic illustrations showing the adapted test apparatus according to the second embodiment of the invention. As shown in FIGS. 6 and 7, the case assembly 10 of this embodiment includes a base 12, an upper cover 14 and a temperature control module 16. The first motherboard assemblies 20 is mounted in the base 12. The upper cover 14 may be moved to cover the base 12 and the first motherboard assemblies 20. The temperature control module 16, disposed in a chamber 18 formed by the upper cover 14 and the base 12, controls the temperature of the chamber 18 or the temperature of the gas in the chamber 18. In one example, the temperature control module 16 includes a heater 17. In another example, the temperature control module may include a gas supply for supplying a gas or gases to the chamber 18 to control the temperature. After the handler 30 finishes inserting the electronic components 100, the handler 30 moves away, and then an oil cylinder 90 of an oil-cylinder suspension frame 95 pushes the upper cover 14 downward to contact the base 12 in a closed manner, so that the tests at some specific temperatures may be performed according to the customer's requirements.

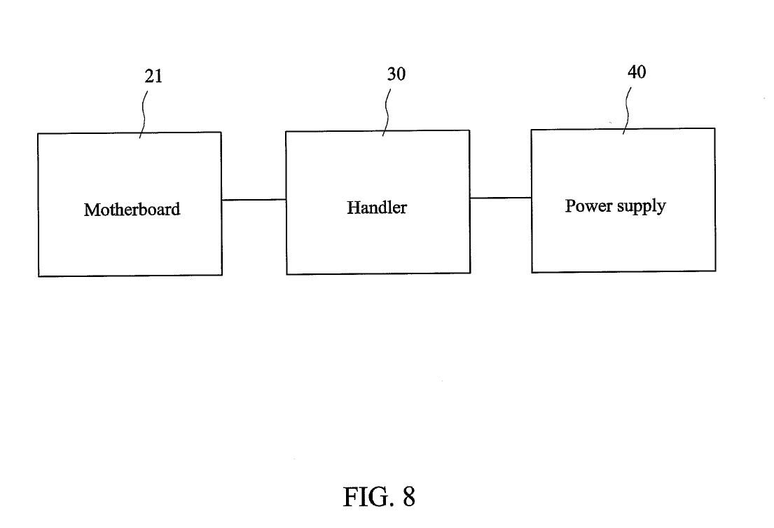

FIG. 8 shows the connection relationships between the handler 30, a power supply and the motherboard 21 according to the invention. Referring to FIG. 8, the test apparatus of the invention may further include a power supply 40 electrically connected to the handler 30. The handler 30 is electrically connected to the motherboard 21, and the handler 30 inserts the electronic components 100 into the test connector 26 and then turns on the power supply 40 and the motherboard 21 to perform the test. After the test is finished, the handler 30 turns off the power supply 40 and the motherboard 21 and then removes the electronic components 100. Therefore, all the test processes can be performed or monitored by the handler 30, and the number of the required testers can be significantly decreased.

The test processes will be described in the following. First, the handler 30 takes the electronic component(s) 100 from the temporary storage area 50, inserts the electronic component(s) 100 into the test connector 26, then turns on the motherboard 21 and then reads whether the signal of the motherboard 21 is normal. If the signal is abnormal, the motherboard 21 is turned off or shut down, and the electronic component 100 is replaced with a new one for test. If the signal of the motherboard 21 is normal, the above-mentioned procedures are repeated to insert the electronic components 100 into the other motherboards 21 in the case assembly 10. The power-on test of the motherboard usually needs a long period of time, such as 1,500 to 3,000 seconds or longer. So, the handler 30 can continue to use the motherboards 21 in the other additional case assemblies 10′ to perform the tests of the other electronic components 100 by repeating the above-mentioned steps. After all the case assemblies 10′ have been occupied by the electronic components 100, it is determined whether the test times are due. If not, the waiting is continued. If the test time is due, the signal of each motherboard 21 is read to judge whether the test result of the electronic component 100 is normal, and the electronic component 100 is removed and transported to the coarse classification area 55 according to the test result. In addition, another handler can be provided to transport the electronic component 100 from the coarse classification area 55 to the fine classification area 56.

According to the adapted test apparatus, the adapter 24 enables the handler 30 to insert the electronic component 100 into the test connector 26 in the vertical direction. The horizontally extended dimension of the adapter 24 is very small, and the gap between the upright motherboards 21 can be effectively reduced. So, it is possible to obtain the larger test capacity in the limited chamber, and to effectively decrease the test cost.

While the present invention has been described by way of examples and in terms of preferred embodiments, it is to be understood that the present invention is not limited thereto. To the contrary, it is intended to cover various modifications. Therefore, the scope of the appended claims should be accorded the broadest interpretation so as to encompass all such modifications.

What is claimed is:

1. An adapted test apparatus, comprising:
a case assembly;
a plurality of first motherboard assemblies, each of which is disposed in the case assembly and comprises:
a motherboard vertically disposed in the case assembly;
a first main connector, which is disposed on the motherboard and electrically connected to the motherboard;
an adapter, which is electrically connected to the first main connector and substantially perpendicular to the motherboard;
a plurality of test connectors disposed on the adapter; and
a central processing unit (CPU), which is disposed on the motherboard and electrically connected to the motherboard; and
a handler for inserting a plurality of electronic components into the test connectors in a vertical direction, respectively, testing the electronic components and removing the electronic components after the electronic components have been tested.

2. The test apparatus according to claim 1, further comprising:
a power supply electrically connected to the handler, wherein the handler is electrically connected to the motherboard, the handler inserts the electronic component into the test connector, then turns on the power supply and the motherboard to test the electronic component, turns off the power supply and the motherboard after the electronic component is tested, and then removes the electronic component.

3. The test apparatus according to claim 1, further comprising:
a coarse classification area, wherein the handler moves the electronic components, which have been tested, to the coarse classification area according to a plurality of test results, respectively.

4. The test apparatus according to claim 1, further comprising:
a temporary storage area, wherein the handler takes the electronic component out of the temporary storage area and then inserts the electronic component into the test connector.

5. The test apparatus according to claim 1, wherein the case assembly comprises:
a base, wherein the first motherboard assemblies are mounted in the base;
an upper cover, which may be moved to cover the base and the first motherboard assemblies; and
a temperature control module, disposed in a chamber formed by the upper cover and the base, for controlling a temperature of the chamber.

6. The test apparatus according to claim 5, wherein the temperature control module comprises a heater.

7. The test apparatus according to claim 1, wherein the handler takes multiple electronic components of the electronic components at a time.

8. The test apparatus according to claim 1, wherein each of the first motherboard assemblies further comprises:
a heat dissipating fan disposed on the CPU; and
a video card disposed on the motherboard.

9. The test apparatus according to claim 1, further comprising a plurality of additional case assemblies, wherein the case assembly and the additional case assemblies are disposed in a machine casing, and the case assembly and the additional case assemblies may be moved out of the machine casing for maintenance.

10. The test apparatus according to claim 1, further comprising:
a positioning-pressing mechanism, disposed on the adapter, for positioning the electronic component and pressing the electronic component into the test connector.

11. The test apparatus according to claim 10, wherein the positioning-pressing mechanism comprises:
a first positioning structure aligned with and disposed on the test connector;
a second positioning structure, aligned with and disposed on the first positioning structure, for positioning the electronic component;
a pressing block for pressing the electronic component into the test connector;
a pressing mechanism for exerting a force on the pressing block; and
a second suspension frame, wherein the pressing mechanism is movably mounted on the second suspension frame.
